(19) United States
(12) Patent Application Publication
(10) Pub. No.: US 2026/0082526 A1
(43) Pub. Date: Mar. 19, 2026

(54) COOLING COMPONENT FOR HEAT DISSIPATION

(71) Applicant: ERWIN QUARDER SYSTEMTECHNIK GMBH, Espelkamp (DE)

(72) Inventors: Georg SIEWERT, Pohlheim (DE); Alexander KRISTOF, Minden (DE); Alexander HEITBRINK, Stemwede (DE); Stefan BRUNS, Osnabrück (DE)

(73) Assignee: ERWIN QUARDER SYSTEMTECHNIK GMBH, Espelkamp (DE)

(21) Appl. No.: 19/395,309

(22) Filed: Nov. 20, 2025

Related U.S. Application Data
(63) Continuation of application No. PCT/EP2024/064162, filed on May 23, 2024.

(30) Foreign Application Priority Data
May 24, 2023 (DE) 102023113542.2

(51) Int. Cl. H05K 7/20

(52) U.S. Cl. CPC H05K 7/20927; H05K 7/209

(57) ABSTRACT

A cooling component for the dissipation of heat from objects to be cooled, includes an inlet through which cooling medium can be supplied to the cooling component, with flow channels connected in parallel through which the cooling medium supplied via the inlet flows, and an outlet through which the cooling medium can be discharged from the cooling component, in particular, after the absorption of heat from an object to be cooled. The cooling component comprises at least one deflection device arranged downstream of the parallel flow channels, to which the cooling medium flowing in a main flow direction through at least one of these parallel flow channels is led and from which the cooling medium is diverted laterally so that it continues to flow laterally downstream of the deflection device offset to the aforesaid main flow direction.

### CROSS-REFERENCE TO RELATED APPLICATIONS

This patent application is a continuation of, and as such claims priority to, International Patent Application No. PCT/EP2024/064162, filed on May 23, 2024, which claims priority to and all advantages of German Patent Application No. DE 10 2023 113 542.2, filed on May 24, 2023; each of the foregoing applications are incorporated herein by reference in their entireties.

### BACKGROUND

Cooling components that a cooling medium flows through or can flow through are used, for example, for power electronics components, such as power electronics semiconductor modules, or high-performance chips. It is desirable for cooling components to be particularly efficient with a high level of performance and usually have a metallic heat sink, i.e., a heat sink made of metal or a metal alloy (possibly coated) with a preferably level or flat heat absorption side formed by a cooling surface, which is as close as possible when the cooling component is used in order to optimize heat transfer—under direct installation or by means of an intermediate layer of thermal interface material, in particular thermal paste—thereby being arranged on a (for example, also plan) heat emission side of the object to be cooled. The heat sink then absorbs the waste heat of the object to be cooled, which, in turn, is then dissipated by the cooling medium. The cooling medium flows inside the cooling component through the flow channels of the cooling component.

JP 2016 062919 A discloses a heat sink wherein a body to be cooled is attached to the bottom part and/or the lid and wherein a pair of first inner fins are arranged on the side of an inlet/outlet opening for a cooling medium. The second inner fins are arranged next to each other in the latitudinal direction via the passages, wherein a space is open from the end of the pair of first inner fins and the other side of the inlet/outlet.

### SUMMARY

This disclosure relates to a cooling component for dissipating heat from objects to be cooled, with an inlet via which cooling medium can be supplied to the cooling component, with flow channels connected in parallel through which the cooling medium can be flowed through by the cooling medium supplied via the inlet, and with an outlet, via which the cooling medium can be discharged from the cooling component, in particular, after absorbing heat from an object to be cooled.

When cooling a plurality of high-performance chips arranged in a matrix, they are often arranged on the cooling surface of the cooling component in such a way that the cooling medium is directed in the flow direction parallel along a plurality of rows of chips successively arranged one after the other. The cooling medium heats up in the process so that the cooling capacity decreases in the flow direction if no countermeasures are taken. In addition, the cooling medium often heats up to different degrees due to a different heat input of the matrix-like chips across the flow direction. For example, further out in the cooling component less strongly than further inside so that, as a result, the further cooling performance further inside the cooling component is significantly weaker than further outside if no countermeasures are taken.

This disclosure further develops a cooling component of the type mentioned at the outset, in particular, in such a way that such effects can be counteracted by appropriately designing the cooling component.

Accordingly, a cooling component is characterized in that the cooling component comprises at least one deflection device arranged downstream from the flow channels connected in parallel, to which the cooling medium is guided, which flows in a main flow direction through at least one of these flow channels connected in parallel, and from which the cooling medium is deflected laterally so that it continues to flow offset laterally downstream from the deflection device to the aforementioned main flow direction, wherein at least one flow channel is a side-flow channel connected in parallel to a heat-sink flow channel of a heat-sink structure of a heat-sink structure of one or part of a heat sink of the cooling component with a plurality of heat sink flow channels, wherein the parallel connected side-flow channel runs in a plane that is parallel at a distance from the plane in which heat sink flow channels of the heat sink structure run.

By using one or a plurality of these deflection devices, it is therefore favourably possible, for example, to redirect a cooling medium located in one of the parallel flow channels that is less heated by one or a plurality of objects to be cooled into an area of the cooling component in which a particularly strong heat input from other objects to be cooled is to be expected as the process progresses or in which, independently of this, for example, a particularly strong heat input should be cooled.

If, for example, the cooling component comprises a plurality of cooling zones successively connected in series one after the other, each with flow channels connected in parallel, which align with each other across the cooling zones, without such a deflection device, the cooling medium flowing further out in the first cooling zone and possibly less heated would also flow further out in the second cooling zone and there it can again be heated less strongly compared to the cooling medium flowing further inwards.

Furthermore, it can be provided that the cooling medium flowing through at least one other of the flow channels connected in parallel is guided within the cooling component in such a way that it is mixed with the cooling medium deflected laterally by the deflection device. In other words, the cooling medium that is heated to a greater or lesser extent and that flows through the flow channel that leads the cooling medium to the deflection device could then be mixed with a correspondingly less or a plurality of strongly heated cooling medium of another flow channel in order to change the temperature of the cooling medium in a targeted manner. It can be provided that the cooling medium, which flows through the further flow channel connected in parallel, is also guided to the deflection device or another deflection device and is then diverted laterally by this in such a way that the mixing can take place. As a result, for example, the deflection device can redirect the cooling medium through the two flow channels in such a way that it flows towards each other.

It can also be provided that the flow channel through which the cooling medium flowing to the deflection device flows and/or the further flow channel is a heat-sink flow channel of a heat-sink structure forming part of a preferably metallic heat sink of the cooling component with a plurality of heat-sink flow channels, in particular, a heat-sink structure the heat-sink flow channels of which are delimited by adjacent fins or pins that are, in particular, spaced away at equal distances.

It is provided that the flow channel through which the cooling medium flowing to the deflection device flows and/or the further flow channel is a side-flow channel connected in parallel to a heat-sink structure forming the heat-sink flow channels of one or part of a heat sink of the cooling component with a plurality of heat-sink flow channels. In particular, a heat-sink structure whose heat-sink flow channels are delimited by adjacent fins or pins that are, in particular, spaced away at equal distances. This can be a side-flow channel that is used to reduce the flow resistance of the heat-sink structure compared to such a heat-sink structure without such a side-flow channel and/or to pass through any particles contained in the cooling medium that do not fit through these heat-sink flow channels where applicable.

Furthermore, it can be provided that the deflection device of the cooling medium comprises a deflection wall, preferably running obliquely to the above-mentioned main flow direction of the cooling medium, which the cooling medium impinges and through which the cooling medium is deflected laterally.

It is provided that the parallel side-flow channel runs in a plane that is parallel at a distance from the plane in which heat-sink flow channels of the heat-sink structure run.

Furthermore, it can be provided that the deflection device is designed and arranged in such a way that cooling medium flowing through the side-flow channel is guided to the deflection device and diverted from it laterally, preferably laterally further inwards. This is done in particular by means of a first deflection wall running diagonally to the main flow direction in the side-flow channel. In addition, the deflection device can be designed and arranged in such a way that cooling medium flowing through the heat-sink flow channel is guided to the deflection device and deflected from it laterally, preferably to the side further outwards. This is done in particular by a second deflection wall running diagonally to the main flow direction in the heat-sink flow channel.

Furthermore, it can be provided that the deflection device comprises a partition wall with two opposite sides separating the cooling medium flowing out of the side-flow channel from the cooling medium flowing out of the heat-sink flow channel, by designing and placing the partition wall in such a way that the cooling medium flowing out of the side-flow channel is guided along one side of the partition wall and the cooling medium flowing out of the heat-sink flow channel is directed along the opposite, other side of the partition wall.

Furthermore, it can be provided that the deflection device is a component separate from the heat sink and its heat-sink structure.

Furthermore, it can be provided that the cooling component has a plurality of cooling zones connected in series and/or a plurality of parallel zones so that they are flowed through successively or in parallel by the cooling medium supplied via the inlet, and each of which has a heat-sink structure with a plurality of heat-sink flow channels, in particular a heat-sink structure whose heat-sink flow channels are delimited by adjacent fins or pins that are, in particular, spaced away at equal distances, and each of which comprises a side-flow channel connected in parallel to the heat-sink flow channels, in particular to reduce the flow resistance of the cooling zone in question compared to such a cooling zone without such a side-flow channel and/or to pass through any particles contained in the cooling medium, where applicable, that do not fit through those heat-sink flow channels.

It can also be provided that the deflection device is arranged between two consecutive cooling zones connected in series.

The deflection device can also be arranged between two consecutive groups of a plurality of cooling zones connected in series, wherein the cooling medium supplied to it from a structural flow channel of a cooling zone further inwards of the group of cooling zones connected in parallel arranged upstream is diverted laterally via the deflection device to a structural flow channel of a cooling zone further outwardly arranged of the group of parallel cooling zones arranged downstream. In addition or as an alternative, it can be provided that the cooling medium supplied to it from a side-flow channel of a cooling zone further out of the group of parallel cooling zones arranged upstream is diverted laterally via the deflection device to a side-flow channel of a cooling zone arranged further inwards of the group of cooling zones connected in parallel arranged downstream.

In this context, it can also be provided that the deflection device diverts the cooling medium supplied to it from a structural flow channel of the upstream cooling zone of the cooling zones connected in series laterally to the side-flow channel of the cooling zone arranged downstream, and/or that the cooling medium supplied to it from a side-flow channel of the upstream cooling zone of the cooling zones connected in series is diverted laterally via the deflection device to a structural flow channel of the cooling zone arranged downstream.

As far as the metallic heat sink is concerned, it can comprise a component made of (coated where applicable) metal or a metal alloy (coated where applicable) or be formed by such a component which, on one side, comprises the heat-sink structure in a material part, which is turned away from a cooling surface of the cooling component, in particular, which is flat, to which an object to be cooled can be brought to rest to absorb heat from it.

As far as the cooling surface of the cooling component is concerned, this can be formed by an (external) side of the heat sink or by an (external) side of another, preferably metallic, in particular plate-shaped cooling component body connected to the heat sink in a thermally conductive manner.

### BRIEF DESCRIPTION OF THE DRAWINGS

FIG. 1 shows a cooling component in oblique view from above,

FIG. 2 shows the cooling component from FIG. 1 in a first exploded illustration.

FIG. 3 shows the cooling component from FIG. 1 in a second exploded illustration.

FIG. 4 shows the cooling component from FIG. 1 in a cross-section.

FIG. 5 shows the cooling component from FIG. 1 in a first longitudinal section.

FIG. 6 shows the cooling component from FIG. 1 in a view from above, omitting an (upper) housing part.

FIG. 7 shows a detail of the cooling component from FIG. 1 in an enlarged illustration, namely a deflection device of the cooling component in an oblique view from above, which is evident in FIGS. 2 and 3.

FIG. 8 shows the cooling component from FIG. 7 in an oblique view from below.

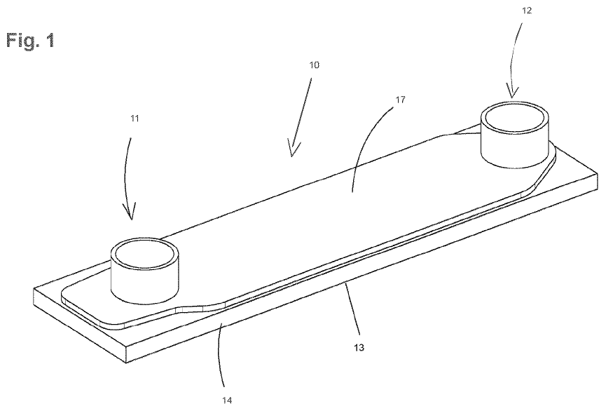

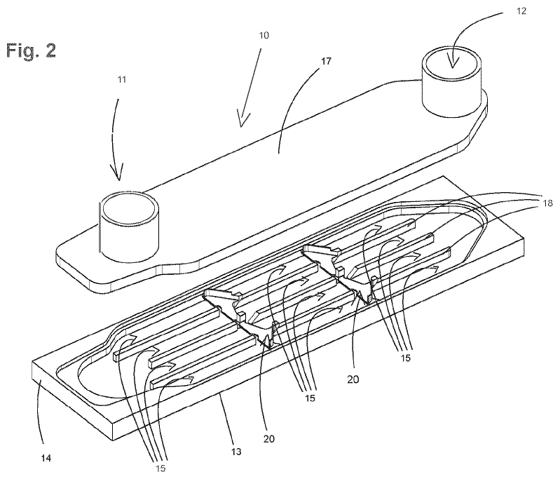

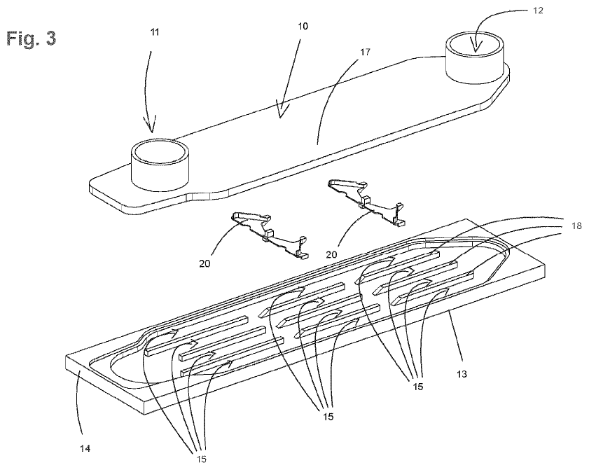

### DETAILED DESCRIPTION

The cooling component 10 shown in the figures, on the bottom side of which objects to be cooled that are not shown can be arranged in order to dissipate heat from them to the cooling component 10, is in the present case part of a higher-level cooling device that is otherwise not shown in more detail.

The cooling device and its cooling component 10 can be used, for example, to cool a plurality of power electronics units, such as power electronics semiconductor modules or high-performance chips. Such power electronic components are used, among other things, in connection with batteries or rechargeable batteries of electric vehicles. However, it is to be understood that the type of components to be cooled does not matter.

The higher-level cooling device can, among other things, have or be filled with a cooling medium that is conveyed by means of a pump through the cooling component 10 so that it flows through the cooling component 10 and absorbs and dissipates heat from the object to be cooled on its way through the cooling component 10. For this purpose, the pump can be connected to an inlet 11 and an outlet 12 of the cooling component 10 by means of medium-conveying pipes, such as hoses for example.

As a rule, the cooling medium will be a cooling medium. However, it is understood that it is also within the scope of the disclosure to use a gaseous medium as a cooling medium.

The cooling component 10 comprises a heat sink 14 made of metal or metal alloy.

In the present case, the heat sink 14 is connected—for example in material-to-material or uniform material manner—to a large number of heat-sink structures or fin structures that are not explicitly shown in the present case (the reference number 15 in the drawings points to the location where they are arranged) with individual thin-walled (material) fins as well as narrow flow channels delimited by these, which are designed as heat-sink flow channels, through which the cooling medium flows during operation of the cooling device, thereby coming from the direction of inlet 11 in the direction of outlet 12.

In other words, the heat sink 14 comprises the aforementioned heat-sink structures, for example, they are milled into them or moulded in some other way.

In the transverse direction of cooling component 10, the individual heat-sink structures are separated from each other by partition walls 18.

Towards the top, the heat sink 14 is covered by a housing part 17, which is made of metal, for example, and is sealed in a fluid-tight manner.

In the present case, the bottom side of the heat sink 14 also forms the lower or heat absorption side 13 of the cooling component 10, to which the components to be cooled are attached in cooling mode.

However, the heat sink 14 could also, for example, be thermally conductively connected on its lower side to another, for example plate-shaped, metallic cooling component body (directly or with the mediation of a heat paste attached to it) so that this further cooling component body or its bottom side would then form the heat absorption side 13 of the cooling component 10. This would be particularly useful in order to be able to manufacture, for example, heat sink 14 from a first (metallic) material with slightly lower thermal conductivity, such as aluminium, which has certain manufacturing advantages, and the other cooling component body that comes into contact with the objects to be cooled from a second (metallic) material that is more thermally conductive than aluminium, such as copper.

In the present case, each heat-sink structure is also part of a separate assigned cooling zone 16a, 16b, 16c or 16d, through which the cooling medium flows.

As further indicated in the drawings, the heat sink 14 in the present case comprises three similar segments A, B and C in succession in the flow direction or longitudinal direction of the cooling component 10, each with four cooling zones 16a-16d, each of which is arranged successively or connected in series with respect to the medium flow resulting from the inlet 11 to the outlet 12.

In other words, various of the cooling zones 16a-16d are connected directly in series across segments so that the medium flow flows through them one after the other.

In relation to each segment A, B and C, the respective cooling zones 16a-16d of a segment A, B and C are also connected in parallel, i.e. the cooling medium flows through them in parallel.

The individual (not shown) fins of the (not shown) heat-sink structures of cooling zones 16a-16d are typically very thin and the heat-sink flow channels they limit are very narrow. However, very narrow heat-sink flow channels generate a high pressure loss. This leads to an unfavourably high flow resistance, especially in view of the series connection of the individual cooling zones 16a-16d in the cooling component 10.

Cooling component 10, i.e., in the present case each cooling zone 16a-16d of the same, therefore comprises a further flow channel extending parallel at a distance from the heat-sink flow channels of the respective cooling zones 16a-16d, which is designed as a side-flow channel 19, which is also connected in parallel to the respective heat-sink flow channels of the respective cooling zone 16a-16d and whose purpose is, among other things, to: reduce the flow resistance of the respective cooling zone 16a-16d.

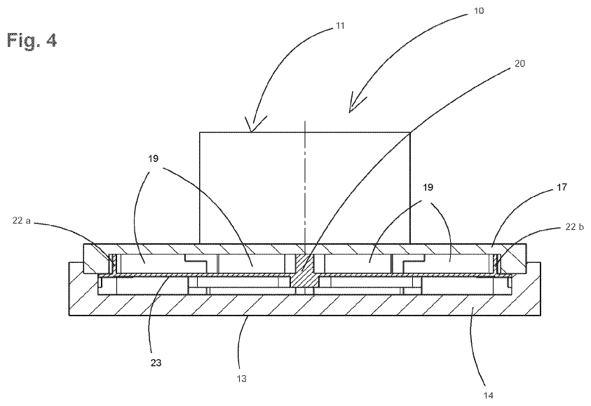

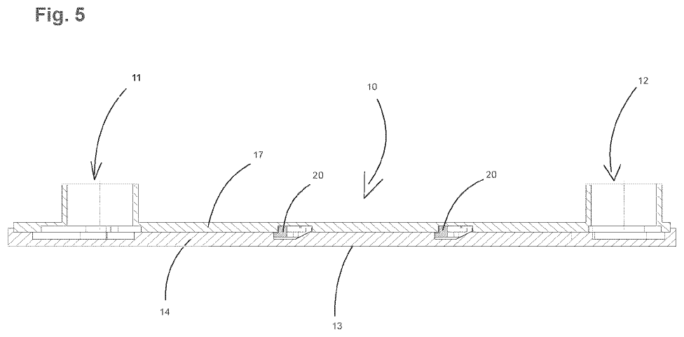

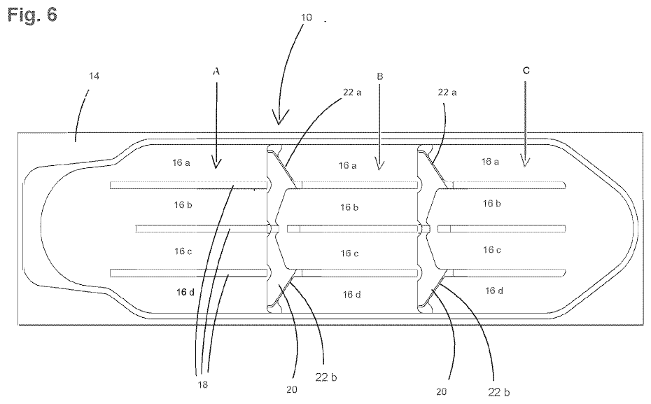

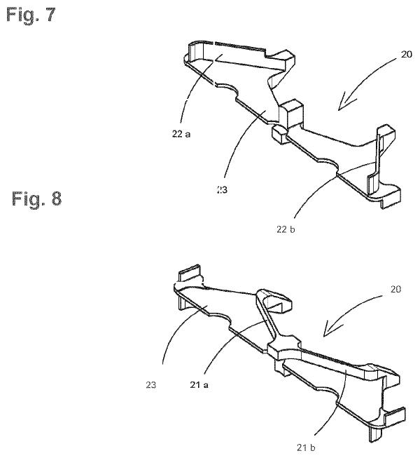

As can be seen in particular in FIG. 4, these side-flow channels 19, which extend parallel to the main flow direction within the heat-sink flow channels, also run, in the present case, above the respective heat-sink structure or its heat-sink flow channels.

The side-flow channels 19 are adjacent to free ends of the fins of the corresponding heat-sink structure on an open (lower) side of the same and to the corresponding open bottom sides of the heat-sink flow channels opposite sides of the heat-sink flow channels of this heat-sink structure, in this case under a fluid-conducting connection with the heat-sink flow channels.

Each side-flow channel 19 of the cooling zones 16a-16d covers a plurality of heat-sink flow channels of the heat-sink structure of the respective cooling zone 16a-16d at right angles to the main flow direction in the side-flow channel 19, in this case at least 80 % of the respective total number of heat-sink flow channels of the respective cooling zone 16a-16d of the same.

To the top and to the side, the side-flow channels 19 and ultimately also the heat-sink flow channels connected to them in a fluid-conductive manner (via the open longitudinal sides) are delimited by corresponding walls of housing part 17 adjacent to the external environment.

It has been shown that the flow resistance of the respective cooling zone 16a-16d can be significantly reduced by the side-flow channels 19 connected parallel to the heat-sink flow channels of the respective cooling zone 16a-16d compared to such a cooling zone 16a-16d without such a side-flow channel 19. This is particularly the case if, as in the present case, the cross-section of the respective side-flow channel 19 is significantly larger than the cross-section of each individual heat-sink flow channel of the respective heat-sink structure of the respective cooling zone 16a-16d or even greater than the sum of the cross-sections of the individual heat-sink flow channels of the same.

If, for example, a plurality of high-performance chips are to be cooled simultaneously with cooling component 10, which are arranged in a matrix-like manner, it is conceivable to arrange them on the cooling surface of cooling component 10 formed by heat absorption side 13 in such a way that they are distributed below the segments A-C so that the cooling medium within cooling component 10 is guided successively along the chips in the flow direction. For example, in the first segment A, a chip to be cooled could be assigned to one of the cooling zones 16a-16d, in the second segment B also one chip to each cooling zone 16a-16d, and so on.

In such an arrangement, the heat input through the chips in the cooling zones located further inwards, here, 16b and 16c, is usually greater than in the cooling zones arranged further out, here, 16a and 16d, which would subsequently lead to different degrees of heating of the cooling medium (less strongly further out than further inside) if no countermeasures are taken, which, in turn, would reduce the cooling capacity from segment to segment in the cooling zones 16b and 16c, which are located further inwards.

The cooling component 10 is intended to counteract this effect. For this purpose, deflection devices 20 are positioned between or in free spaces of the segments A and B or B and C, which are spatially separated from each other in the present case, which deflect the cooling medium flowing from the cooling zones 16a-16d of the respective preceding segment A or B laterally (either horizontally or vertically) and can thus influence the cooling medium temperature and thus the cooling capacity in the cooling zones 16a-16d of the respective subsequent segment B or C.

In the present case, for example, the deflection devices 20 can, for example, deflect the correspondingly cooler cooling medium flowing from the outer side-flow channels 19 of cooling zones 16a and 16d of segment A or B respectively further inwards so that it then flows further inwards in the following segments B and C (then in cooling zones 16b and 16c) and contributes to the stronger cooling performance there.

On the other hand, the more heated cooling medium flowing in the heat-sink flow channels of the inner and middle cooling zones 16b and 16c of segments A and B below the side-flow channels 19 is directed laterally outwards by the deflection devices 20 so that it then flows in the following segments B and C in the outer cooling zones 16a and 16d.

For this purpose, the deflection devices 20 in the present case each comprise a horizontal partition wall 23, which separates the cooling medium that is guided from the side-flow channels 19 (arranged further above) to the deflection devices 20 from the cooling medium that is guided within the heat-sink flow channels (arranged further downstream).

Furthermore, in the area or at the level of the respective side-flow channels 19, the deflection devices 20 each comprise two vertical deflection walls 22a and 22b, each of which runs diagonally to the flows in the side-flow channels 19 and is directed diagonally towards each other, on which the cooling medium of the side-flow channels 19 of the outer cooling zones 16a and 16d impinges and through which the cooling medium is deflected laterally (horizontally) further inwards in the manner described.

In addition, in the area or at the level of the respective heat-sink flow channels, the deflection devices 20 each comprise two vertical deflection walls 21a and 21b, each of which runs diagonally to the flows within the heat-sink flow channels and is directed diagonally towards each other, on which the cooling medium of the heat-sink flow channels of the inner cooling zones 16b and 16c respectively impinges and through which the cooling medium is deflected laterally (horizontally) further outwards in the manner described.

In the present case, the deflection devices 20 are also designed as removable, separate components, but they could also be connected to the heat sink 14 in a single piece or in a uniform material or be formed by it.

It is also to be understood that the deflection devices 20 could also be designed in such a way that a vertical mixing of cooling medium can take place alternatively or additionally, namely a mixing of cooling medium originating from the side-flow channels 19 with cooling medium originating from the heat-sink flow channels.

Such vertical mixing also increases the efficiency of cooling component 10. This is because the side-flow channel 19 is further spaced away from the heat absorption side 13 of the heat sink 14 or the cooling component 10 than the heat-sink flow channels of the respective heat-sink structure so that the cooling medium in the heat-sink flow channels is heated significantly more than the cooling medium in the side-flow channel 19 by the waste heat of the object to be cooled. The aforementioned mixing then ensures that the cooling medium in the side-flow channel 19 also plays an effectively role in the cooling process.

Incidentally, the side-flow channels 19 can serve another purpose—in addition to reducing flow resistance. This is because it can prevent particles contained in the cooling fluid from clogging the very narrow heat-sink flow channels due to their size. This is because these can then flow along the significantly larger side-flow channel 19 and thus be guided out of the cooling component 10 in this way.

In order to ensure that the particles are also guided to the side-flow channel 19, control devices (not shown) can be provided with which they can be directed to the respective side-flow channel 19.

These can be, for example, flanks of the heat-sink structures of the individual cooling zones 16a-16d, each of which has such a flank at their respective upstream end, inclined or obliquely running in relation to the main flow direction in their heat-sink flow channels.

An inclined flank formed in this way can then ensure that dirt particles or other material particles in the cooling medium, which would otherwise clog the heat-sink flow channels, are deflected in the direction of the side-flow channel 19 when the cooling medium impinges the inclined flank and can then flow through it without any problems. The inclined flank of the heat-sink structure could be formed by correspondingly inclined narrow sides of the individual fins of the heat-sink structure.

As already indicated, the side-flow channels are sufficiently large so that the particles that do not fit through the heat-sink flow channels (together with the cooling medium) can flow through them. These can be, for example, particles with a size ≥0.3 mm², especially ≥0.3 mm² and ≤1.2 mm².

All described features of the exemplary embodiments of the present invention explained above on the basis of the drawings are otherwise only to be understood as examples and do not constitute a limitation of the subject-matter according to the invention.

### LIST OF REFERENCE NUMBERS

A-C segments
10 cooling component
11 inlet
12 outlet
13 cooling component heat absorption side
14 heat sink
15 position of heat-sink structures
16a-d cooling zones
17 housing part
18 partition walls for heat-sink structures
19 side-flow channels
20 deflection devices
21a deflection wall for heat-sink structure flow
21b deflection wall for heat-sink structure flow
22a deflection wall for the side flow
22b deflection wall for the side flow
23 partition wall of deflection device

What is claimed is:

1. A cooling component for dissipating heat from objects to be cooled, comprising:
an inlet through which cooling medium is able to be supplied to the cooling component;
flow channels connected in parallel and flowable by cooling medium supplied via the inlet;
an outlet through which the cooling medium is able to be discharged from the cooling component; and
at least one deflection device arranged downstream of the flow channels connected in parallel, to which the cooling medium, which flows through at least one of these parallel flow channels in a main flow direction, is guided and from which the cooling medium is diverted laterally so that it continues to flow laterally downstream from the deflection device offset to the main flow direction;
wherein at least one flow channel is a side-flow channel which is connected in parallel to a heat-sink flow channel of a heat-sink structure forming part of a heat sink of the cooling component comprising a plurality of heat sink flow channels, wherein the parallel connected side-flow channel runs on a plane parallel at a distance from the plane in which heat sink flow channels of the heat-sink structure run.

2. The cooling component according to claim 1, wherein the cooling medium flowing through at least one other of the flow channels connected in parallel is guided in the cooling component in such a way that it is mixed with the cooling medium deflected laterally by the deflection device, by being deflected laterally so that the mixing takes place.

3. The cooling component according to claim 1, wherein
the heat sink includes a plurality of heat-sink flow channels of the heat-sink structure, the heat-sink flow channels of which are delimited from adjacent fins or pins that are spaced away at equal distances; and
the flow channel through which the cooling medium flowing to the deflection device flows is one of the heat-sink flow channels of the heat-sink structure.

4. The cooling component according to claim 1, wherein
the heat sink includes a plurality of heat-sink flow channels of the heat-sink structure;
the flow channel through which the cooling medium flowing to the deflection device flows is a side-flow channel which is connected in parallel to the heat-sink structure forming the heat-sink flow channels; and
the side-flow channel is used for at least one of reducing a flow resistance of the heat-sink structure compared to the heat-sink structure without the side-flow channel or guiding through particles which are contained in the cooling medium and which do not fit through the heat-sink flow channels.

5. The cooling component according to claim 1, wherein the deflection device includes a deflection wall preferably running obliquely to the main flow direction of the cooling medium, on which the cooling medium impinges and by which the cooling medium is deflected laterally.

6. The cooling component according to claim 1, wherein the deflection device is designed and arranged such that cooling medium flowing through the side-flow channel is guided to the deflection device and is diverted from the deflection device laterally by a first deflection wall of the deflection device running obliquely to the main flow direction in the side-flow channel, and that cooling medium flowing through the heat-sink flow channel is guided to the deflection device and diverted from the deflection device laterally by a second deflection wall of the heat-sink flow channel running obliquely to the main flow direction in the heat-sink flow channel.

7. The cooling component according to claim 6, wherein the deflection device includes a partition wall with two opposite sides separating the cooling medium flowing out of the side-flow channel from the cooling medium flowing out of the heat-sink flow channel, the partition wall being designed and placed such that the cooling medium exiting from the side-flow channel is guided along one side of the partition wall and the cooling medium flowing out of the side-flow channel is discharged from the heat-sink flow channel along an opposite side of the partition wall.

8. The cooling component according to claim 1, wherein the deflection device is a component separate from the heat sink and its heat-sink structure.

9. The cooling component according to claim 1, wherein
the cooling component comprises a plurality of cooling zones connected in at least one of series or parallel so that the cooling zones are flowed through successively or in parallel by cooling medium supplied via the inlet;
each cooling zone comprises a heat-sink structure with a plurality of heat-sink flow channels;
each heat-sink flow channel is delimited by adjacent fins or pins that are spaced at equal distances; and
the cooling zones each comprise a side-flow channel connected parallel to the heat-sink flow channels to at least one of reduce a flow resistance of the respective cooling zone compared to the cooling zone without the side-flow channel or guide through any particles contained in the cooling medium that do not fit through the heat-sink flow channels.

10. The cooling component according to claim 9, wherein the deflection device is arranged between two consecutive cooling zones connected in series.

11. The cooling component according to claim 10, wherein
the deflection device is arranged between two consecutive groups of the cooling zones connected in parallel; and
one of (1) the cooling medium supplied to the deflection device from the heat-sink flow channel of one of the cooling zones of the group of parallel-connected cooling zones arranged further inwards upstream is diverted laterally via the deflection device to a structural flow channel of one of the cooling zones arranged further outwards of the group of cooling zones connected in parallel arranged downstream, or (2) the deflection device diverts cooling medium supplied to the deflection device from a side-flow channel of one of the cooling zones arranged further out of the group of cooling zones connected in parallel arranged upstream to a side-flow channel of one of the cooling zones arranged further inwards of the group of cooling zones connected in parallel arranged downstream.

12. The cooling component according to claim 10, wherein (1) one of the cooling medium supplied to the deflection device from a structural flow channel of one of the cooling zones connected in series arranged upstream is diverted laterally to the side-flow channel of one of the cooling zones arranged downstream, or (2) the deflection device diverts cooling medium which is supplied to the deflection device from a side-flow channel of one of the cooling zones connected in series via the deflection device upstream of the cooling zones connected in series, laterally to a structural flow channel of one of the cooling zones arranged downstream.

13. The cooling component according to claim 1, wherein the heat sink includes a component of metal which, on one side, comprises the heat-sink structure in a material part, which is turned away from a cooling surface of the cooling component to which an object to be cooled is able to be brought to rest for absorption of heat from the heat sink.

14. The cooling component according to claim 1, wherein a cooling surface of the cooling component is formed by a side of the heat sink or by a side of a further cooling component body connected to the heat sink in a thermally conductive manner.
